(19) United States
(12) Patent Application Publication
(10) Pub. No.: US 2026/0150612 A1
(43) Pub. Date: May 28, 2026

(54) SURFACE CONDITIONING PROCESSES FOR SEMICONDUCTOR PROCESSING CHAMBER PARTS

(71) Applicant: Applied Materials, Inc, Santa Clara, CA (US)

(72) Inventors: Abhishek Mandal, Thane, Maharashtra (IN); Aminul Islam Sk, Kolkata, West Bengal (IN); Nitin Deepak, Maharashtra (IN); Amir H. Tavakoli, San Jose, CA (US); Jianqi Wang, Fremont, CA (US); Nilesh Patil, Dist -Thane (IN); Gopi Chandran Ramachandran, Mumbai (IN); Jennifer Y. Sun, Sunnyvale, CA (US)

(73) Assignee: Applied Materials, Inc, Santa Clara, CA (US)

(21) Appl. No.: 19/014,676

(22) Filed: Jan. 9, 2025

(30) Foreign Application Priority Data
Nov. 27, 2024 (IN) 202441092692

(51) Int. Cl. H01L 21/67; C23C 16/44; H01L 21/302

(52) U.S. Cl. CPC H10P 72/0408; C23C 16/4404; H10P 50/00

(57) ABSTRACT

Surface conditioning processes for semiconductor processing chamber parts are described. The surface conditioning processes can be used to condition a ceramic material surface in a semiconductor processing chamber.

### CROSS-REFERENCE TO RELATED APPLICATIONS

This application claims priority to Indian Application No. 202441092692, filed Nov. 27, 2024, the entire disclosure of which is hereby incorporate by reference herein.

### TECHNICAL FIELD

Embodiments of the disclosure relate to the field of semiconductor device manufacturing. More particularly, embodiments of the disclosure are directed to surface conditioning processes for semiconductor processing chamber parts.

### BACKGROUND

Ceramic materials are widely used in the course of semiconductor device manufacture. Ceramic materials are processed with a series, or multiple series, of mechanical methods. These mechanical processes (e.g., grinding or bead blasting) create defects such as micro-cracks, which may lead to failure during device operation. In attempt to address the issues caused by the defects, corrosion resistant coatings have been applied on ceramics to enhance and increase lifetime of the parts. However, these corrosion resistant coatings typically require a defect free surface, and when there are defects such as micro-cracks in the surface, there is typically poor adhesion between the surface and the corrosion resistant coating. Accordingly, a smooth surface needs to be conditioned to develop strongly adhered coatings and remove underlying defects such as micro-cracks to avoid peeling off the coating materials. In order to form a smooth surface, an etching process is typically performed in attempt to remove the underlying defects in a surface.

Current wet etching methods use highly concentrated inorganic bases or inorganic acids at elevated temperatures. It has been found that using highly concentrated inorganic bases or inorganic acids at elevated temperatures over-etches the surface, changes composition-intrinsic property, and introduces additional foreign elements into the surface.

There is a need for improved surface conditioning processes to not only remove the underlying surface defects, but also create anchoring points to enable improved adhesion before applying a coating. There is also a need for improved surface conditioning processes that retain the inherent composition of the core ceramic composite material for use in its respective semiconductor device application.

### SUMMARY

One or more embodiments of the disclosure are directed to a method comprising: treating an aluminum-containing surface with a hydroxyl compound to form a treated surface.

Additional embodiments of the disclosure are directed to a method comprising: treating an aluminum-containing surface with a hydroxyl compound to form a treated surface, the hydroxyl compound having a concentration in a range of from 0.5 wt. % to 50 wt. % solution; performing a cleaning process to form a cleaned surface; and drying the cleaned surface by exposing the cleaned surface to a flow of nitrogen (N₂) gas. In some embodiments, the cleaning process includes one or more of: exposing the treated surface to deionized water; exposing the treated surface to one or more of isopropyl alcohol, methanol, or acetone; or exposing the treated surface to one or more of lactic acid, nitric acid, sulfuric acid, or hydrofluoric acid.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of the disclosure and are therefore not to be considered limiting of its scope, for the disclosure may admit to other equally effective embodiments. The embodiments described herein are illustrated by way of example and not limitation in the Figure(s) of the accompanying drawings in which like references indicate similar elements.

FIG. 1 illustrates a process flow diagram of a method in accordance with one or more embodiments of the disclosure.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

Many of the details, dimensions, angles, and other features shown in the Figure(s) are merely illustrative of particular embodiments. Accordingly, other embodiments can have other details, components, dimensions, angles, and features without departing from the spirit or scope of the present disclosure. In addition, further embodiments of the disclosure can be practiced without several of the details described below.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

Spatially relative terms, such as “beneath,” “below,” “lower,” “above,” “upper” and the like, may be used herein for ease of description to describe one element's relationship to another element(s) or feature(s).

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments,” “some embodiments,” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in some embodiments,” “in one embodiment,” or “in an embodiment” in various places throughout this specification are not necessarily referring to the same embodiment of the disclosure. In one or more embodiments, the particular aspects, structures, materials, or characteristics are combined in any suitable manner.

As used in this specification and the appended claims, the term “substrate” or “wafer” can be used interchangeably, both referring to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” or “substrate surface”, as used herein, refers to any portion of a substrate or portion of a material surface formed on a substrate upon which film processing is performed. In some embodiments, the substrate includes a patterned flat substrate.

For example, a substrate surface on which processing can be performed includes materials such as silicon, silicon oxide, silicon nitride, doped silicon, germanium, gallium arsenide, glass, sapphire, and any other materials such as metals, metal nitrides, metal alloys, and other conductive materials, depending on the application.

In some embodiments, the substrate includes at least one conductive material and at least one dielectric material.

Substrates can include, without limitation, semiconductor substrates/semiconductor materials. In some embodiments, the semiconductor substrate comprises one or more of doped or undoped crystalline silicon (Si), doped or undoped crystalline silicon germanium (SiGe), doped or undoped amorphous silicon (Si), or doped or undoped amorphous silicon germanium (SiGe).

Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate. Substrates may have various dimensions, such as 200 mm or 300 mm diameter wafers, as well as rectangular or square panes. In some embodiments, the substrate comprises a rigid discrete material.

The substrate may have one or more features formed therein, one or more layers formed thereon, or combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls comprising, for example, a dielectric material, and a bottom extending into the substrate, the bottom comprising, for example, a metallic material, or vias which have one or more sidewalls extending into the substrate to a bottom.

The features described herein can extend vertically into the substrate and/or laterally within the substrate. Unless specifically indicated otherwise, the features described herein are not limited to either of a vertically extending feature or a laterally extending feature. In one or more embodiments, the substrate comprises at least one vertically extending feature. In one or more embodiments, the substrate comprises at least one laterally extending feature. In one or more embodiments, the substrate comprises at least one vertically extending feature and at least one laterally extending feature.

The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, 40:1, 50:1, 60:1, 70:1, 80:1, 90:1, 100:1, 125:1, or 150:1. In one or more embodiments, the aspect ratio of the features described herein is in a range of from 1:1 to 150:1.

The term “on” indicates that there is direct contact between elements. The term “directly on” indicates that there is direct contact between elements with no intervening elements.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

Embodiments of the present disclosure are directed to surface conditioning processes for semiconductor processing chamber parts. The surface conditioning processes can be used to condition a ceramic material surface in a semiconductor processing chamber. In some embodiments, the ceramic material surface comprises an aluminum-containing surface.

The surface conditioning processes can be used to condition any semiconductor processing chamber part including a ceramic material surface, including, but not limited to, a heater, an electrostatic chuck, an edge ring, a nozzle, a lid, a lift pin, or a lift pin assembly. The semiconductor processing chamber part can be located in a processing system, connected to the processing system, and/or within a semiconductor processing chamber that is part of the processing system.

Some embodiments are directed to surface conditioning processes that are configured to condition a surface and sustain the integrity of the surface material. Some embodiments are directed to surface conditioning processes that employ organic bases and maintain the composition of the surface being conditioned.

Some embodiments are directed to surface conditioning processes that are configured to remove micro-cracks (e.g., a micro-crack having a depth in a range of from 1 μm to 5 μm) with controlled etching. Some embodiments are directed to surface conditioning processes that are configured to create anchoring points for improved adhesion of corrosion resistant coating. Some embodiments are directed to surface conditioning processes that are configured to increase roughness of the surface being treated, leading to improved adhesion of a corrosion resistant coating material deposited thereon. Some embodiments are directed to surface conditioning processes that are performed at or around room temperature, which advantageously provides an easy to scale process and low operational costs.

The embodiments of the disclosure are described by way of the Figure(s), which illustrate a process flow diagram of a method 100. The processes shown are merely illustrative possible uses for the disclosed processes, and the skilled artisan will recognize that the disclosed processes are not limited to the illustrated applications.

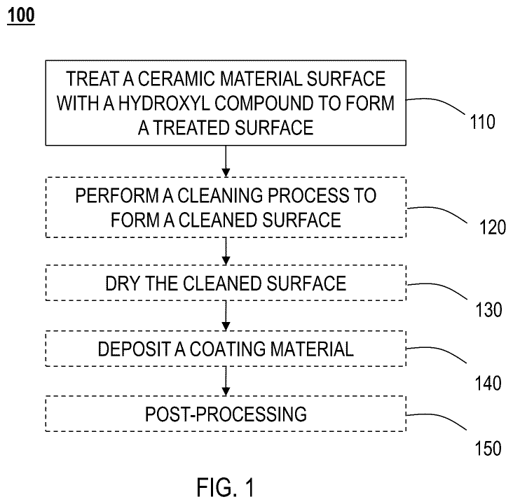

FIG. 1 illustrates a process flow diagram of the method 100. The method 100 includes a surface conditioning process performed on a ceramic material surface. In one or more embodiments, the ceramic material surface is a substrate or wafer. As will be understood and appreciated by the skilled artisan, the surface conditioning process of the method 100 can be preceded by one or more operations. The one or more operations performed prior to the method 100 may vary based upon the application which the ceramic material surface, is to be used.

With reference to FIG. 1, the method 100 comprises, consists essentially of, or consists of: treating a ceramic material surface with a hydroxyl compound to form a treated surface (operation 110); optionally performing a cleaning process to form a cleaned surface (operation 120); optionally drying the cleaned surface (operation 130); optionally depositing a coating material on the cleaned surface (operation 140); and optionally performing one or more post-processing steps (operation 150).

As used in this specification and the appended claims, the term “provided” means that ceramic material surface is made available for processing (e.g., positioned in a processing system, connected to the processing system, and/or positioned within a semiconductor processing chamber that is part of the processing system).

In one or more embodiments, the method 100 begins by treating the ceramic material surface with a hydroxyl compound to form a treated surface at operation 110.

The skilled artisan will appreciate that while portions of the disclosure may discuss various ceramic materials, a “ceramic material surface” as used herein is not limited to any particular ceramic material. In one or more embodiments, the ceramic material surface is an aluminum-containing surface.

In one or more embodiments, the method 100 begins by treating an aluminum-containing surface with a hydroxyl compound to form a treated surface at operation 110.

The aluminum-containing surface can be any surface that includes aluminum. In some embodiments, the aluminum-containing surface comprises one or more of aluminum nitride (AlN), aluminum oxide (Al₂O₃), or aluminum oxynitride (AlON).

In some embodiments, the aluminum-containing surface is doped with a dopant. In some embodiments, the aluminum-containing surface is doped with yttrium. In some embodiments, the aluminum-containing surface comprises one or more of yttrium aluminum garnet (YAG), yttrium aluminum perovskite (YAP), or yttrium aluminum monoclinic (YAM).

The hydroxyl compound used to treat the ceramic material surface (e.g., the aluminum-containing surface) to form the treated surface, at operation 110, can be any compound that includes a functional group with the chemical formula −OH and is composed of one oxygen atom covalently bonded to one hydrogen atom.

In some embodiments, the hydroxyl compound is ammonium hydroxide (NH₄OH), sodium hydroxide (NaOH), or potassium hydroxide (KOH). In some embodiments, the hydroxyl compound is ammonium hydroxide (NH₄OH). In some embodiments, the hydroxyl compound is sodium hydroxide (NaOH). In some embodiments, the hydroxyl compound is potassium hydroxide (KOH). In some embodiments, the hydroxyl compound is [(CH₃)₃NCH₂CH₂OH]⁺OH⁻ (choline hydroxide).

In some embodiments, the hydroxyl compound has a general formula of (R₁R₂R₃R₄)NOH, where each of R1, R₂, R₃, and R₄ independently comprises an alkyl group. Each alkyl group may independently be substituted or unsubstituted.

In some embodiments, the hydroxyl compound is tetramethyl ammonium hydroxide (TMAH). In some embodiments, the hydroxyl compound is tetraethyl ammonium hydroxide (TEAH), tetrapropyl ammonium hydroxide (TPAH), tetrabutyl ammonium hydroxide (TBAH), tributylmethyl ammonium hydroxide (TBMAH), diethyldimethylammonium hydroxide (DMDEAH), or ethyltrimethylammonium hydroxide (ETMAH).

In some embodiments, treating the ceramic material surface (e.g., the aluminum-containing surface) with the hydroxyl compound to form the treated surface, at operation 110, comprises immersing the ceramic material surface (e.g., the aluminum-containing surface) in a solution of the hydroxyl compound. As used herein, the concentration of the solution of the hydroxyl compound can be referred to as “wt. % solution.”

In some embodiments, the hydroxyl compound has a concentration in a range of from 0.5 wt. % to 80 wt. % solution. In some embodiments, the hydroxyl compound has a concentration in a range of from 60 wt. % to 80 wt. % solution. In some embodiments, the hydroxyl compound has a concentration in a range of from 70 wt. % to 80 wt. % solution. In some embodiments, the hydroxyl compound has a concentration in a range of from 25 wt. % to 50 wt. % solution.

In some embodiments, treating the aluminum-containing surface with the hydroxyl compound to form the treated surface, at operation 110, is performed at a temperature in a range of from 5° C. to 50° C. In some embodiments, treating the aluminum-containing surface with the hydroxyl compound to form the treated surface, at operation 110, is performed at a temperature of 25° C.

In some embodiments, treating the ceramic material surface (e.g., the aluminum-containing surface) with the hydroxyl compound to form the treated surface, at operation 110, is performed for a time period in a range of from 5 minutes to 5 hours. In some embodiments, treating the ceramic material surface (e.g., the aluminum-containing surface) with the hydroxyl compound to form the treated surface, at operation 110, is performed for a time period of 2 hours.

In some embodiments, treating the ceramic material surface (e.g., the aluminum-containing surface) with the hydroxyl compound to form the treated surface, at operation 110, is configured to condition the ceramic material surface (e.g., the aluminum-containing surface), sustain the integrity of, and maintain the composition of, the ceramic material surface (e.g., the aluminum-containing surface).

In some embodiments, treating the ceramic material surface (e.g., the aluminum-containing surface) with the hydroxyl compound to form the treated surface, at operation 110, non-selectively etches the ceramic material surface and advantageously provides a treated surface having a more uniform surface chemistry and a better surface roughness/finish as compared to a selectively etched surface.

The electrical insulation and high thermal conductivity properties of aluminum nitride (AlN), for example, may be useful for high power electronic applications as a heat sink and spreader. AlN heaters, for example, exhibit surface damage/morphology change post-chamber operation. Without intending to be bound by theory, it has been found that heater coatings exhibit vertical micro-cracks caused by preexisting micro-cracks on the heater surface. The micro-cracks are believed to form during mechanical surface finishing (e.g., grinding or bead blasting). It has also been found that the micro-cracks propagate along grain boundaries of the aluminum-containing surface, e.g., the AlN heaters.

In some embodiments, treating the ceramic material surface with the hydroxyl compound to form the treated surface, at operation 110, is configured to reduce an amount of surface defects in the ceramic material surface compared to a ceramic material surface that is not treated with the hydroxyl compound described herein.

In some embodiments, treating the aluminum-containing surface with the hydroxyl compound to form the treated surface, at operation 110, is configured to reduce an amount of surface defects in the aluminum-containing surface compared to an aluminum-containing surface that is not treated with the hydroxyl compound described herein.

In some embodiments, treating the ceramic material surface (e.g., the aluminum-containing surface) with the hydroxyl compound to form the treated surface, at operation 110, is configured to remove micro-cracks from the ceramic material surface (e.g., the aluminum-containing surface). In specific embodiments, treating the ceramic material surface (e.g., the aluminum-containing surface) with the hydroxyl compound to form the treated surface, at operation 110, is configured to remove micro-cracks independently having a depth in a range of from 1 μm to 5 μm with controlled etching from the ceramic material surface (e.g., the aluminum-containing surface).

In some embodiments, treating the ceramic material surface (e.g., the aluminum-containing surface) with the hydroxyl compound to form the treated surface, at operation 110, is configured to create anchoring points for improved adhesion of corrosion resistant coating (e.g., a coating material that is deposited on the treated surface).

In one or more embodiments, micro-hills (hexagonal pyramids) features have been observed in ceramic material surfaces (e.g., aluminum-containing surfaces), which are critical to enhance adhesion of coatings. In some embodiments, treating the ceramic material surface (e.g., the aluminum-containing surface) with the hydroxyl compound to form the treated surface, at operation 110, is advantageously configured to remove surface defects, retain the material composition and hexagonal pyramids suitable for better adhesion.

In some embodiments, the method 100 comprises performing a cleaning process after forming the treated surface to form a cleaned surface at operation 120. The cleaning process includes one or more of: exposing the treated surface to deionized water; exposing the treated surface to one or more of isopropyl alcohol, methanol, or acetone; or exposing the treated surface to one or more of lactic acid, nitric acid, sulfuric acid, or hydrofluoric acid.

In some embodiments, the cleaning process comprises, consists essentially of, or consists of exposing the treated surface to deionized water. In some embodiments, the cleaning process comprises, consists essentially of, or consists of exposing the treated surface to one or more of isopropyl alcohol, methanol, or acetone. In some embodiments, the cleaning process comprises, consists essentially of, or consists of exposing the treated surface to one or more of lactic acid, nitric acid, sulfuric acid, or hydrofluoric acid.

In some embodiments, the method 100 comprises performing the cleaning process after forming the treated surface to form the cleaned surface at operation 120 and repeating one or more of: exposing the treated surface to deionized water; exposing the treated surface to one or more of isopropyl alcohol, methanol, or acetone; or exposing the treated surface to one or more of lactic acid, nitric acid, sulfuric acid, or hydrofluoric acid. The cleaning process, i.e., one or more of: exposing the treated surface to deionized water; exposing the treated surface to one or more of isopropyl alcohol, methanol, or acetone; or exposing the treated surface to one or more of lactic acid, nitric acid, sulfuric acid, or hydrofluoric acid, can be repeated any suitable number of times.

In some embodiments, the method 100 comprises drying the cleaned surface at operation 130. In some embodiments, at operation 130, the method 100 comprises drying the cleaned surface by exposing the cleaned surface to a flow of nitrogen (N₂) gas.

In some embodiments, the method 100 comprises depositing a coating material at operation 140. In some embodiments, the coating material is deposited directly on the treated surface. In some embodiments, the coating material is deposited directly on the cleaned surface. In some embodiments, the coating material is deposited directly on the cleaned surface after drying the cleaned surface.

The coating material can be deposited by any suitable deposition technique. Advantageously, it has been found that treating the ceramic material surface (e.g., the aluminum-containing surface) with the hydroxyl compound to form the treated surface, at operation 110, which is configured to reduce an amount of surface defects in the ceramic material surface (e.g., the aluminum-containing surface) compared to a ceramic material surface, such as an aluminum-containing surface, that is not treated with the hydroxyl compound described herein, improves the quality of the coating material deposited.

In some embodiments, the method 100 comprises performing one or more post-processing steps at operation 150. The one or more post-processing steps of operation 150 may vary based upon the application which the ceramic material surface (e.g., the aluminum-containing surface), is to be used.

The methods described herein can be performed any suitable processing system. The particular arrangement of processing chambers and components in the processing system can be varied depending on the processing system and should not be taken as limiting the scope of the disclosure.

Processes may generally be stored in the memory of a system controller as a software routine that, when executed by the processor, causes the processing system to perform one or more of the operations of any of the methods described herein. The software routine may also be stored and/or executed by a second processor (not shown) that is remotely located from the hardware being controlled by the processor. Some or all of the methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the processing system operation such that one or more of the operations of any of the methods described herein are performed.

One or more embodiments of the disclosure are directed to a non-transitory computer readable medium including instructions that, when executed by a controller of a processing system, causes the processing system to perform one or more of the operations of any of the methods described herein.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure includes modifications and variations that are within the scope of the appended claims and their equivalents.

What is claimed is:

1. A method comprising:
treating an aluminum-containing surface with a hydroxyl compound to form a treated surface.

2. The method of claim 1, wherein the aluminum-containing surface comprises one or more of aluminum nitride (AlN), aluminum oxide (Al₂O₃), or aluminum oxynitride (AlON).

3. The method of claim 1, wherein the hydroxyl compound is ammonium hydroxide (NH₄OH), sodium hydroxide (NaOH), potassium hydroxide (KOH), or [(CH₃)₃NCH₂CH₂OH]⁺OH⁻ (choline hydroxide).

4. The method of claim 1, wherein the hydroxyl compound has a general formula of (R₁R₂R₃R₄)NOH, where each of R1, R₂, R₃, and R₄ independently comprises an alkyl group.

5. The method of claim 4, wherein the hydroxyl compound is tetramethyl ammonium hydroxide (TMAH).

6. The method of claim 4, wherein the hydroxyl compound is tetraethyl ammonium hydroxide (TEAH), tetrapropyl ammonium hydroxide (TPAH), tetrabutyl ammonium hydroxide (TBAH), tributylmethyl ammonium hydroxide (TBMAH), diethyldimethylammonium hydroxide (DMDEAH), or ethyltrimethylammonium hydroxide (ETMAH).

7. The method of claim 1, wherein the hydroxyl compound has a concentration in a range of from 0.5 wt. % to 80 wt. % solution.

8. The method of claim 7, wherein the hydroxyl compound has a concentration in a range of from 25 wt. % to 50 wt. % solution.

9. The method of claim 1, performed at a temperature in a range of from 5 °C. to 50 °C.

10. The method of claim 9, performed at a temperature of 25 °C.

11. The method of claim 1, performed for a time period in a range of from 5 minutes to 5 hours.

12. The method of claim 11, performed for a time period of 2 hours.

13. The method of claim 1, further comprising depositing a coating material on the treated surface.

14. The method of claim 1, wherein the treated surface has an amount of surface defects that is reduced compared to an aluminum-containing surface that is not treated with the hydroxyl compound.

15. The method of claim 1, wherein the aluminum-containing surface is located within a semiconductor processing chamber.

16. The method of claim 1, further comprising performing a cleaning process after forming the treated surface to form a cleaned surface, the cleaning process including one or more of:
exposing the treated surface to deionized water;
exposing the treated surface to one or more of isopropyl alcohol, methanol, or acetone; or
exposing the treated surface to one or more of lactic acid, nitric acid, sulfuric acid, or hydrofluoric acid.

17. The method of claim 16, comprising repeating one or more of:
exposing the treated surface to deionized water;
exposing the treated surface to one or more of isopropyl alcohol, methanol, or acetone; or
exposing the treated surface to one or more of lactic acid, nitric acid, sulfuric acid, or hydrofluoric acid.

18. The method of claim 16, further comprising drying the cleaned surface by exposing the cleaned surface to a flow of nitrogen (N₂) gas.

19. A method comprising:
treating an aluminum-containing surface with a hydroxyl compound to form a treated surface, the hydroxyl compound having a concentration in a range of from 0.5 wt. % to 50 wt. % solution;
performing a cleaning process to form a cleaned surface, the cleaning process including one or more of:
exposing the treated surface to deionized water;
exposing the treated surface to one or more of isopropyl alcohol, methanol, or acetone; or
exposing the treated surface to one or more of lactic acid, nitric acid, sulfuric acid, or hydrofluoric acid; and
drying the cleaned surface by exposing the cleaned surface to a flow of nitrogen (N₂) gas.

20. The method of claim 19, further comprising depositing a coating material on the cleaned surface.
